(19) United States
(12) Patent Application Publication
(10) Pub. No.: US 2011/0259262 A1
(43) Pub. Date: Oct. 27, 2011

(54) SYSTEMS AND METHODS FOR GROWING MONOCRYSTALLINE SILICON INGOTS BY DIRECTIONAL SOLIDIFICATION

(75) Inventors: Chandra P. Khattak, Nashua, NH (US); Santhana Raghavan Parthasarathy, Nashua, NH (US); Bhuvaragasamy G. Ravi, Nashua, NH (US)

(73) Assignee: GT SOLAR, INC., Merrimack, NH (US)

(21) Appl. No.: 12/999,439

(22) PCT Filed: Jun. 15, 2009
(86) PCT No.: PCT/US09/47395

§ 371 Date: May 24, 2011

Related U.S. Application Data
(60) Provisional application No. 61/061,826, filed on Jun. 16, 2008.

(51) Int. Cl. C30B 11/02

(52) U.S. Cl. 117/81; 117/223; 117/201

(57) ABSTRACT

Systems and methods are provided for producing monocrystalline materials such as silicon, the monocrystalline materials being usable in semiconductor and photovoltaic applications. A crucible (50) is received in a furnace (10) for growing a monocrystalline ingot, the crucible (50) initially containing a single seed crystal (20) and feedstock material (90), where the seed crystal (20) is at least partially melted, and the feedstock material (90) is completely melted in the crucible (50), which is followed by a growth and solidification process. Growth of monocrystalline materials such as silicon ingots is achieved by directional solidification, in which heat extraction during growth phases is achieved using insulation (14) that is movable relative to a crucible (50) containing feedstock (90). A heat exchanger (200) also is provided to control heat extraction from the crucible (50) during the growth and solidification process to achieve monocrystalline growth.

### CROSS-REFERENCE TO RELATED APPLICATION

This application claims the benefit of copending application U.S. Provisional Application Ser. No. 61/061,826 filed on Jun. 16, 2008, the disclosure of which is expressly incorporated herein by reference in its entirety.

### FIELD OF INVENTION

The subject invention is directed to systems and methods for producing monocrystalline materials. More particularly, the subject invention relates to systems and methods for producing monocrystalline silicon for solar cell applications.

### DESCRIPTION OF THE RELATED ART

A monocrystalline structure can be exhibited by a solid material in which the crystal lattice of the entire structure is continuous and unbroken to the edges of the structure, with substantially low defects and no grain boundaries. Since defects in conventional crystal structures typically occur at the grain boundaries, these defects tend to degrade the electrical and thermal properties of the material. As a result, high interfacial energy and relatively weak bonding in most grain boundaries can make them preferred sites for the onset of problems and for the precipitation of new unwanted phases of the solid. A multicrystalline structure generally is a crystalline material that is produced in such a way that many small, randomly oriented, crystals (or crystallites) form. These crystallites are bounded by grain boundaries. The crystallites of a multicrystalline material can be intermingled and interspersed, whereas the atoms within a crystallite or a monocrystalline structure are symmetrically arranged. The numerous defects at the grain boundaries of a multicrystalline structure can reduce the efficiency of any device which is formed relative to a device formed from a monocrystalline material.

Monocrystalline materials such as silicon have important industrial applications, for example, in the semiconductor and photovoltaic industries. For example, in semiconductor applications, where microprocessors operate on a quantum scale, the presence of grain boundaries can have a significant impact on the functionality of field effect transistors by altering local electrical properties. Similarly, when using materials such as silicon for solar cells, monocrystalline silicon solar cells generally exhibit high efficiencies, as compared to multicrystalline silicon solar cells. Because grain boundaries generally exhibit more impurities and defects, a solar cell made of monocrystalline silicon should be capable of increased performance as compared to one made of multicrystalline silicon.

Common techniques for commercial production of silicon ingots include: the Czochralski method, the Bridgman growth technique and directional solidification. The Czochralski method is the most common ingot pulling technique for commercially-produced monocrystalline silicon ingots. According to the Czochralski method, high-purity, semiconductor-grade silicon can be melted down in a crucible, which is typically made of quartz. A seed crystal, mounted on a rod, is dipped into the molten silicon, and the seed crystal's rod is pulled upwards and rotated at the same time. By precisely controlling the temperature gradients, the rate of pulling and the speed of rotation, it is possible to extract a large, single-crystal, cylindrical ingot from the melt. The Czochralski method, while it produces nearly defect free silicon ingots, is very expensive. Another disadvantage is the increased impurity content (such as oxygen) introduced by the crucible. Oxygen is introduced into silicon as the result of a reaction between the crucible and molten silicon; this reaction is promoted by rotation of the ingot and counter rotation of the crucible in the Czochralski process. Moreover, when lower quality silicon feedstock is used, various secondary phases can form and float on the surface of the melt. During pulling of the ingot, these secondary phases can result in structural breakdown, resulting in a lower quality product. Because of the added cost of the Czochralski process, crystalline silicon wafers produced for photovoltaic applications generally are multicrystalline.

The Bridgman technique is another known method of growing silicon ingots. The Bridgman growth technique involves heating crystalline material above its melting point and subsequently solidifying it at a controlled growth rate and temperature gradient. The heat exchanger method (HEM) is an example of a Bridgman-type technique. According to this process, a seed crystal is placed at the bottom of a crucible and feedstock is loaded as a charge. When the charge is molten, the seed is prevented from melting by forcing a coolant gas through a heat exchanger, which acts as a cold finger. Solidification of the charge is achieved by increasing the flow of coolant gas through the heat exchanger, thereby creating a temperature gradient in the solid and promoting growth of the charge. The furnace temperature can also be decreased during this growth. As a result, there is substantially no movement of the heat zone or the charge during a growth cycle. In a typical Bridgman furnace, a gradient is built into the heat zone and the furnace and/or the crucible containing the charge is moved to achieve controlled solidification.

With conventional directional solidification systems, multicrystalline growth has been achieved on a production scale. For example, in a directional solidification system, a crucible containing a charge can be placed on a heat exchanger block. The charge is melted and heat radiates to a water cooled chamber to produce a temperature gradient and promote solidification of the charge. In such a case, melting and solidification are carried out in the same crucible. Directional solidification can also be carried out in a separate crucible after, or at approximately the same time as, silicon is poured into it from a melting crucible. The approach of using a melting crucible and a solidification crucible is usually referred to as casting. However, in industry, directional solidification and casting often are used interchangeably for multicrystalline ingot production. For purposes of the subject invention, directional solidification refers to a method of crystalline silicon ingot formation where melting and solidification is carried out in the same crucible. With directional solidification, the ingot and/or the crucible are not rotated, and thus oxygen concentration in a directionally solidified silicon ingot generally is lower than that in an ingot produced by the Czochralski process. Either induction heating or resistance heating can be used in a directional solidification process. Unlike Czochralski growth, solidification in directional solidification is achieved from the bottom of the crucible to the top, so the solid/liquid interface is submerged during most of the growth cycle, and secondary phases/precipitates floating at the surface of the melt do not disrupt growth.

While directional solidification is most common in the industrial environment, there can be some disadvantages. As mentioned above, defects typically occur with multicrystalline structures, and can result in non-uniform properties in the silicon ingot. In addition, impurity contents in the material contacting the crucible can be high depending on the type of crucibles used, and sometimes, portions of the bottom, sides, and top surface of the ingot must be discarded. Thus, the primary tradeoff of current directional solidification techniques is lower cost at the expense of solar cell efficiency. For example, multicrystalline solar cells typically are about 85% to 90% as efficient as monocrystalline cells.

In view of the disadvantages of the known methods, there is a need for a cost effective process for producing silicon ingots with monocrystalline structures.

### SUMMARY OF THE INVENTION

The subject invention relates to systems and methods for producing materials, such as silicon, having a monocrystalline structure. The subject invention can achieve the benefit of producing a high quality monocrystalline product while retaining the cost efficiency and time savings achieved by known directional solidification techniques.

The subject invention can produce a monocrystalline structure from a single seed crystal placed in a crucible by integrating two or more mechanisms for controlled heat extraction. A furnace for promoting directional solidification preferably is used, where the furnace includes insulation that can be moved, i.e., raised or lowered, relative to an ingot being formed, resulting in heat radiation from bottom edges of the crucible, in order to facilitate both vertical and horizontal growth of the seed crystal during the growth process.

Preferably an ingot is grown from a single seed placed in the crucible, such that the seed has sufficient room to grow in both the vertical and horizontal directions within the crucible. The shape of the crucible may be selected from a number of geometric designs including rectangular, conical and tapered shapes. The insulation contained in the furnace includes insulation arranged along the sides of the furnace, and insulation arranged under a heat exchanger block. Other locations and configurations of insulation, whether fixed or movable, are contemplated by the subject invention.

In contrast to monocrystalline structures formed from a plurality of seed crystals arranged on a common substrate or otherwise provided in a matrix form, the monocrystalline structure according to the subject invention preferably is formed from a single seed crystal placed in a crucible, which facilitates both vertical and horizontal growth of the ingot, and can prevent cross contamination between multiple seeds.

The subject invention can provide additional heat extraction by incorporating a gas-cooled heat exchanger for controlling the meltback of the seed crystal and extracting heat during the growth and solidification process to achieve monocrystalline growth of the ingot. Alternatively, instead of being gas cooled, the heat exchanger can be water or liquid cooled. Additional heat extraction during solidification can be achieved by lowering insulation that is arranged directly under the crucible, such that the insulation is moved away from the crucible in order to promote cooling and heat loss from the bottom of the crucible.

In certain embodiments, the crucible may be provided with a seed well in order to facilitate stable positioning of the seed.

A further heat extraction and heat control method provided by the subject invention is the use of support structures positioned between the crucible and the heat exchanger. The support structures also provide additional structural integrity to the system.

The subject invention therefore has the benefit of minimizing nucleation of spurious grains to achieve a monocrystalline structure and, thereafter, controlling directional solidification to promote growth of the ingot.

Another advantage of monocrystalline wafers used to produce solar cells is that substantially the entire surface has the same orientation and can be treated to achieve uniform results for the entire surface. For example, if the wafers are texture etched, small pyramids can be formed over the entire surface, allowing light incident on the surface to undergo multiple reflections and thereby enable more light to be trapped in the solar cells. This phenomenon also can make monocrystalline wafers more efficient solar cells as compared to multicrystalline wafers.

For solar cell applications, because monocrystalline wafers generally have substantially the same orientation over their entire surface, when such a wafer is etched, it can form uniform textures over the entire surface. For example, wafers having (100) orientation will form pyramids, and wafers having (111) orientation will form triangles, where the (100) and (111) orientations are known to those skilled in the art. For smooth surfaces, at least part of the incident light is reflected, whereas for textured surfaces, at least some of the reflected light can be redirected, and thus end up recaptured by the surface. Therefore, in general, more light is trapped for textured surfaces. Reflection off pyramid structures is generally recaptured to a greater extent as compared to triangle structures, and thus pyramid structures are generally preferred over other orientations. By contrast, in multicrystalline wafers, different orientations are formed at different areas of the wafers, and thus texturing is generally not effective and not reproducible. However, as described above, in monocrystalline wafers, it is preferable to form uniform textures over the entire surfaces of such wafers.

The subject invention provides a system for producing monocrystalline ingots, which includes a furnace for promoting monocrystalline growth of a seed arranged in a crucible, such that growth of the seed is promoted in both vertical and horizontal directions by directional solidification. The crucible is configured to receive a single seed crystal and feedstock material; at least one heating element for heating and at least partially melting the seed crystal contained in the crucible; a heat exchanger, for example a gas-cooled heat exchanger, for controlling the melting of the seed crystal and the feedstock material; and insulation contained in the furnace, for example, along the sides of the furnace, and configured to move relative to the chamber for cooling and solidifying the seed crystal in order to form a monocrystalline ingot. The crucible preferably is placed in a chamber of the furnace. According to the subject invention, the insulation can be raised or lowered relative to the crucible in order to control radiant heat losses. Optionally, insulation can be provided under a heat exchanger block, such insulation also being configured to move up and down.

The heat exchanger of the subject invention is operable in a plurality of stages to control a rate of melting of the seed crystal in the crucible. In one stage, a gas is forced into the heat exchanger to prevent substantially complete melting of the seed crystal. In another stage, a flow of the gas in the heat exchanger is increased to promote directional solidification off the single seed crystal.

The system of the subject invention may further include a probe or thermocouple to monitor the melting of the feedstock material and meltback of the seed. The feedstock material is typically a polycrystalline silicon feedstock. The system of the subject invention may form a monocrystalline ingot such that the upper surface has a slightly convex or planar shape. Additionally, in case of perturbation during monocrystalline ingot production according to the subject invention, if grain boundaries are formed, the grain size will be larger than multicrystalline ingots produced by conventional processes.

The subject invention also provides a method for producing a monocrystalline ingot. The method of the subject invention includes the steps of: providing a furnace configured to promote monocrystalline growth by directional solidification; placing a single crucible of a desired geometric shape containing a single seed crystal and feedstock material in a heat zone of the furnace; heating and at least partially melting the seed crystal, and completely melting the feedstock material contained in the crucible; operating a heat exchanger to control the melting of the seed crystal and the feedstock material; and providing movable insulation under the crucible and in the furnace such that the insulation is configured to be raised or lowered for cooling and solidifying the molten silicon relative to the chamber in order to promote directional solidification off the seed crystal and form the monocrystalline ingot. The method of the subject invention may further include the step of monitoring the melting of the feedstock material.

In operation, a gas can be introduced into the heat exchanger to prevent substantially complete melting of the seed crystal. Further, the flow of the gas into the heat exchanger can be increased to promote directional solidification off the seed crystal. The heat exchanger is operable in a plurality of stages of monocrystalline growth and solidification.

The subject invention also provides a method for producing a monocrystalline silicon ingot useful for photovoltaic applications. The method includes the steps of: providing a furnace configured to promote monocrystalline growth by directional solidification; placing a crucible containing a seed crystal and silicon feedstock material in a heat zone of the furnace; heating and at least partially melting the seed crystal, and completely melting the feedstock material contained in the crucible; operating a heat exchanger to control the melting of the seed crystal and the feedstock material by introducing a gas into the heat exchanger at a controlled rate; and providing movable insulation in the furnace, the insulation configured to be raised or lowered for cooling and solidifying the seed crystal in order to form the monocrystalline silicon ingot. Like the system of the subject invention, the insulation can be raised or lowered relative to the chamber to promote directional solidification off the seed crystal.

In operation, a gas introduced into the heat exchanger can be controlled by feedback obtained by monitoring melting of the feedstock material and the seed crystal or from the thermocouple positioned inside the heat exchanger near the bottom of the crucible. In response to the feedback, a gas flow into the heat exchanger is increased, thus increasing heat extraction by the heat exchanger, to promote directional solidification off the seed crystal.

These and other aspects and advantages of the subject invention will become more readily apparent from the following description of the preferred embodiments taken in conjunction with the drawings.

### BRIEF DESCRIPTION OF THE DRAWINGS

So that those skilled in the art to which the subject invention appertains will readily understand how to make and use the method and device of the subject invention without undue experimentation, preferred embodiments thereof will be described in detail herein below with reference to certain figures, wherein:

FIG. 1 is a cross-sectional schematic view of a directional solidification furnace having a rectangular-shaped crucible useful for preparing monocrystalline ingots according to a first preferred embodiment of the subject invention, in which side insulation is provided in a closed configuration;

FIG. 2 is a cross-sectional schematic view of the furnace of FIG. 1 in which the side insulation is provided in a generally open configuration;

FIG. 3A is a cross-sectional schematic view of a heat zone of the furnace of FIG. 1 after loading of a seed and a charge;

FIG. 3B is a cross-sectional schematic view of the heat zone of FIG. 3A after the charge is molten and the melted back seed is in a solid state;

FIG. 3C is a cross-sectional schematic view of the heat zone of FIG. 3B during an initial growth phase of a monocrystalline ingot;

FIG. 3D is a cross-sectional schematic view of the heat zone of FIG. 3C during a second growth phase of the monocrystalline ingot;

FIG. 3E is a cross-sectional schematic view of the heat zone of FIG. 3B during a final growth and solidification phase of the monocrystalline ingot;

FIGS. 4A to 4E are cross-sectional schematic views of a heat zone of a directional solidification furnace having a conical-shaped crucible, during various stages of loading, melting, and growth according to a second preferred embodiment of the subject invention, where the various stages depicted in FIGS. 4A-4E correspond to those depicted in FIGS. 3A-3E, respectively;

FIGS. 5A to 5E are cross-sectional schematic views of a heat zone of a directional solidification furnace having a conical-shaped crucible, in which a corresponding support structure is provided at a bottom of the crucible for added structural integrity and to control the heat flow, during various stages of loading, melting, and growth according to a third preferred embodiment of the subject invention, where the various stages depicted in FIGS. 5A-5E correspond to those depicted in FIGS. 3A-3E, respectively;

FIGS. 6A to 6E are cross-sectional schematic views of a heat zone of a directional solidification furnace having a tapered-shaped crucible with a seed well portion for securing the seed in place, during various stages of loading, melting, and growth according to a fourth preferred embodiment of the subject invention, where the various stages depicted in FIGS. 6A-6E correspond to those depicted in FIGS. 3A-3E, respectively; and

FIGS. 7A to 7E are cross-sectional schematic views of a heat zone of a directional solidification furnace having a tapered-shaped crucible with a seed well portion for securing the seed in place, in which a corresponding support structure is provided at a bottom of the crucible for added structural integrity and to control the heat flow, during various stages of loading, melting, and growth according to a sixth preferred embodiment of the subject invention, where the various stages depicted in FIGS. 7A-7E correspond to those depicted in FIGS. 3A-3E, respectively.

### DETAILED DESCRIPTION OF THE INVENTION

Preferred embodiments of the subject invention are described below with reference to the accompanying drawings, in which like reference numerals represent the same or similar elements.

The subject invention relates to systems and methods of growing monocrystalline materials. While the description herein discusses production of monocrystalline silicon, the techniques and methods described herein are not limited to the production of monocrystalline silicon or silicon only. A number of monocrystalline materials can be produced using the method of the subject invention such as semiconductor crystals (for example, Ge, GaAs, etc.), oxides (for example, sapphire, YAG, ALON), and fluorides (for example, MgF₂, CaF₂), etc.

Current efforts to commercially produce monocrystalline materials such as silicon generally employ radiant heat extraction. The system and method of the subject invention can be used to produce monocrystalline ingots by modifying the directional solidification process to produce a product substantially without grain boundaries, while maintaining low cost, large ingot sizes, high yield, and the ability to use lower quality, less expensive feedstock. Further, in case of perturbation during monocrystalline ingot production according to the subject invention, if grain boundaries are formed, the grain size will be larger as compared to multicrystalline ingots prepared by conventional processes. In order to achieve these results, the subject invention preferably uses at least two sources of controlled heat extraction: a gas-cooled heat exchanger and insulation configured to be moved relative to a crucible contained within a directional solidification furnace substantially so as not to disturb the solid-liquid interface. These and other modifications of the directional solidification process can be used to achieve growth of monocrystalline materials such as silicon. Preferably the modified directional solidification process can be used to produce large-scale silicon ingots on the order of about 10 cm to more than about 100 cm (diameter or square) with preferred sizes greater than about 12 cm square cross section for solar cell applications. Moreover, nearly planar surfaces of the solid-liquid interface can be achieved which allow the growth of larger, heavier ingots substantially without residual stress.

According to the subject invention, a gas-cooled heat exchanger can be used to achieve seeding and promote crystal growth in a directional solidification process, as described in greater detail described below. Preferably, directional solidification is controlled so as to grow an ingot while maintaining a monocrystalline structure and minimizing conditions that may cause the solid-liquid interface to undergo nucleation of spurious grains.

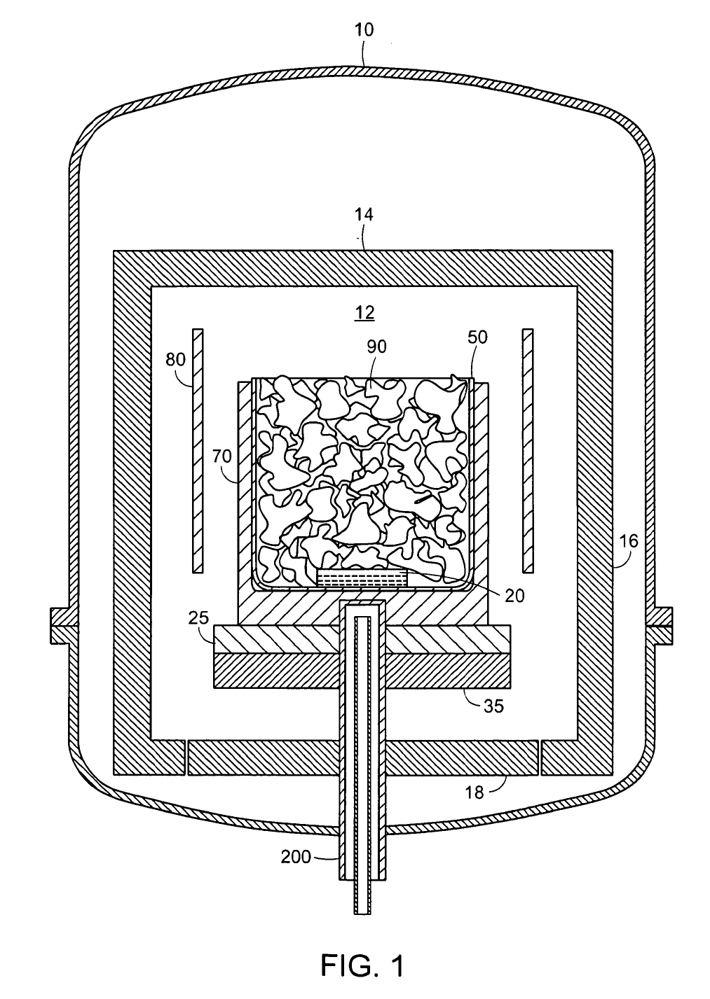

Referring to FIG. 1, a system for producing monocrystalline ingots preferably includes a furnace 10 defining a chamber, where the furnace is configured to promote directional solidification inside the chamber. A single seed crystal 20 preferably is placed in a crucible 50 positioned in a heat zone (also referred to herein as a “hot zone”) of the furnace 10. A gas-cooled heat exchanger 200, for example, a helium-cooled heat exchanger, is arranged at approximately the bottom of the crucible 50, thereby acting a cold finger on the seed 20. Alternatively, instead of a gas-cooled heat exchanger, a heat exchanger that is water or liquid cooled can be used.

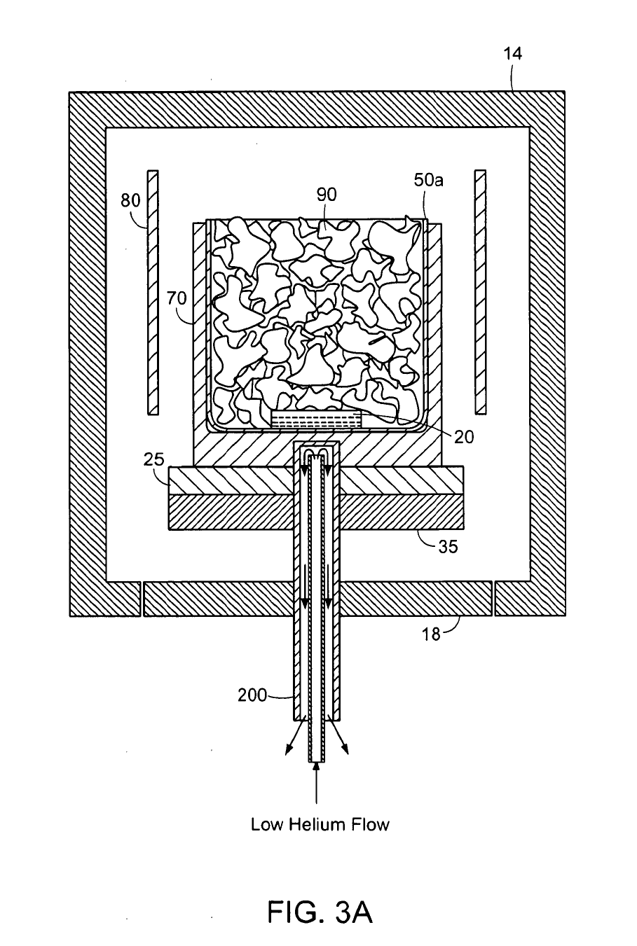

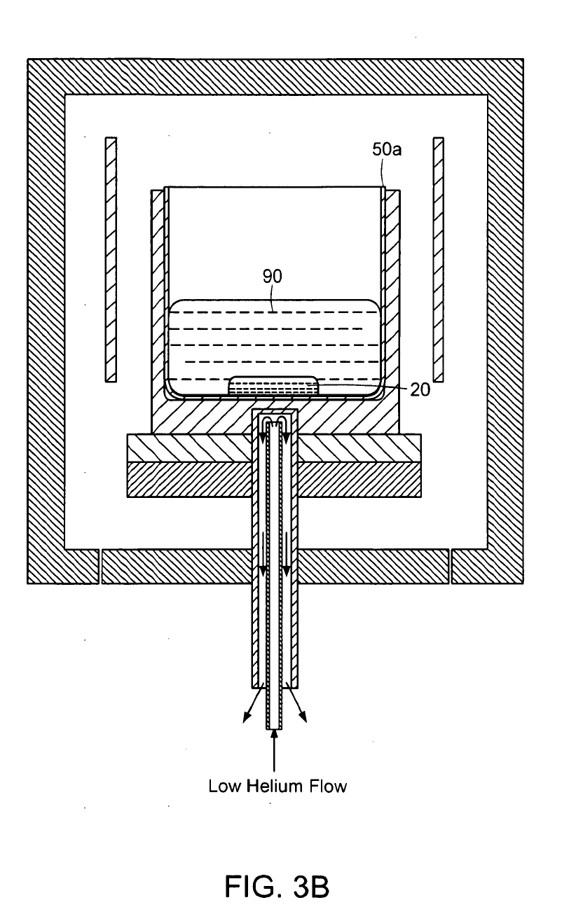

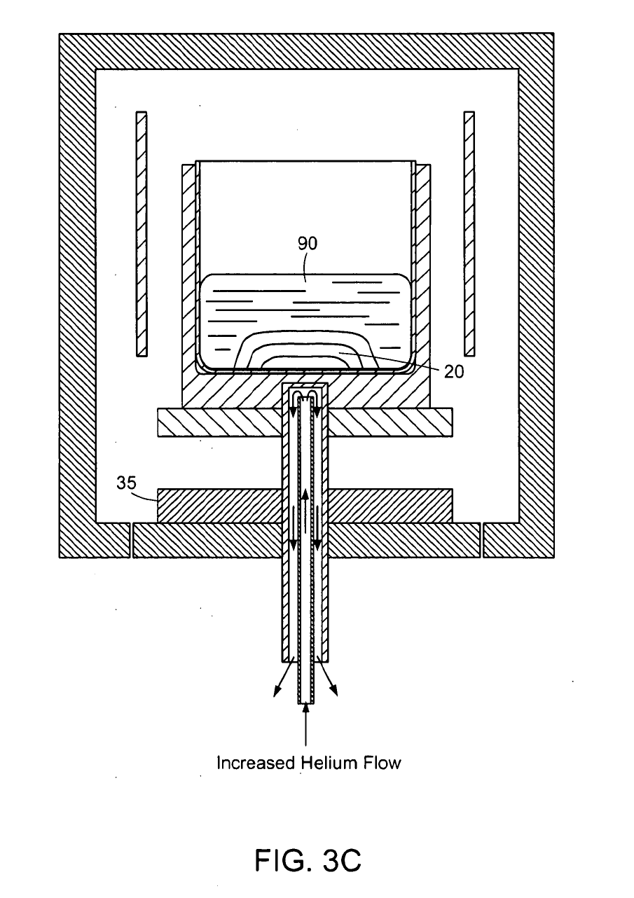

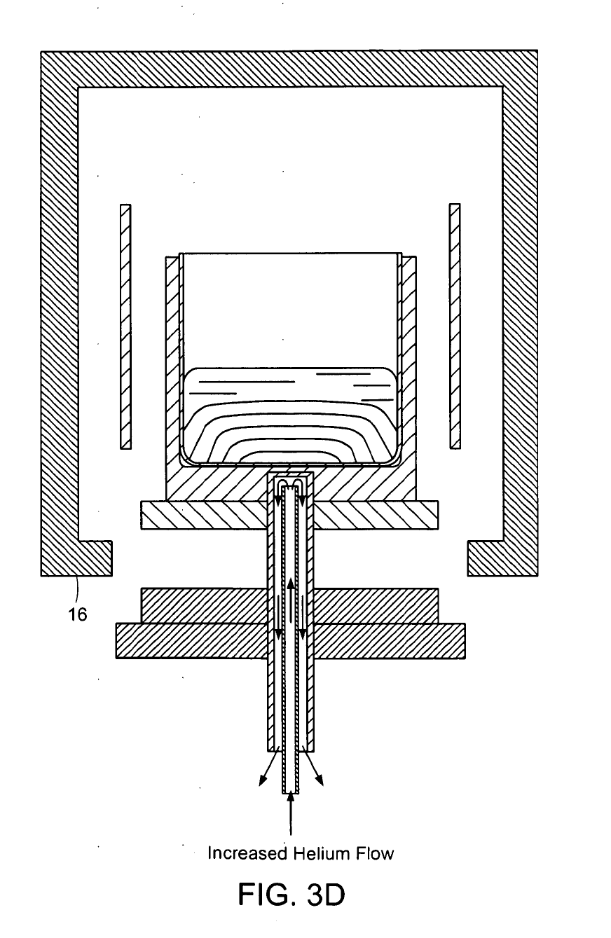

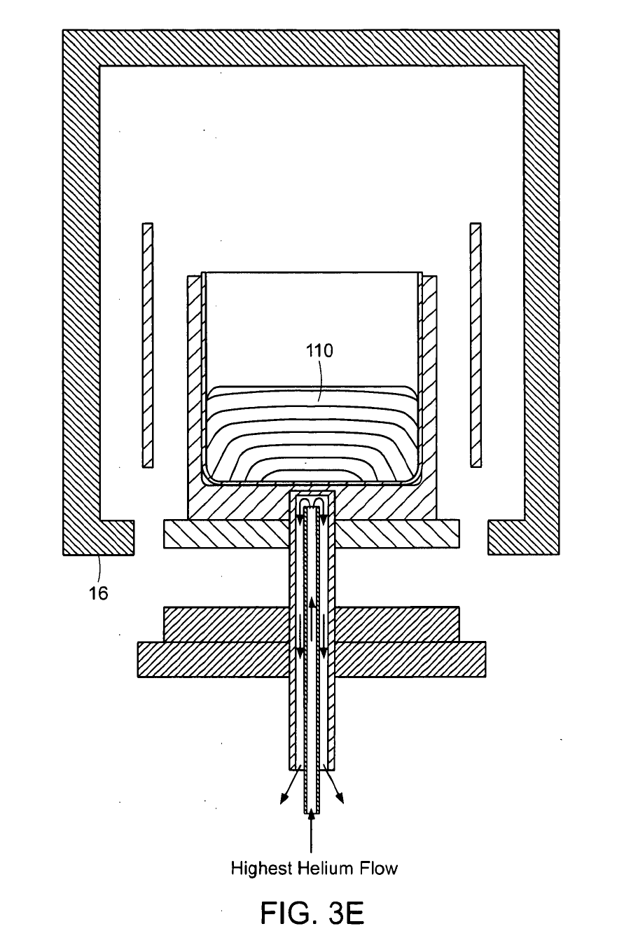

The crucible 50 and the seed 20 received within the furnace 10 are contained in the chamber defined by an interior of the furnace 10, where the chamber preferably is a water-cooled chamber in which a controlled atmosphere can be maintained. A rectangular-shaped crucible 50a can be loaded with a feedstock 90 or charge, for example, polycrystalline silicon feedstock (see FIG. 3A). The feedstock 90 is arranged to be heated by at least one heating element 80 fixed within the furnace 10. Melting of the feedstock 90 preferably is controlled by regulating the power to the at least one heating element 80, and meltback of the seed 20 is determined by controlling gas flow through the heat exchanger 200. Preferably, the power to the heating element 80 is regulated so as to completely melt the feedstock 90, and to only partially melt the seed 20, while substantially avoiding complete melting of the seed 20.

After the feedstock 90 is molten and the seed 20 is at least partially melted, the flow of gas through the heat exchanger 200 is increased to initiate and sustain growth. After sufficient growth, further solidification is achieved by cooling the crucible 50 by gradually increasing radiant heat losses. This is achieved by moving the insulation 14 relative to the crucible 50 so as not to disturb the solid to liquid interface of the growing ingot. A mechanism for monitoring the meltback of the feedstock 90 may also be provided in the system, such as a probe or thermocouple (not shown), or other means known in the art. Once the monocrystalline ingot is formed, the ingot may remain in the furnace 10 and may be allowed to anneal and cool within the crucible 50 itself.

A method of forming a monocrystalline ingot is also provided by the subject invention. While the subject invention will be described below in terms of the formation and growth of monocrystalline silicon, the subject invention is not limited to the production of silicon, nor to the exemplary operating parameters described herein.

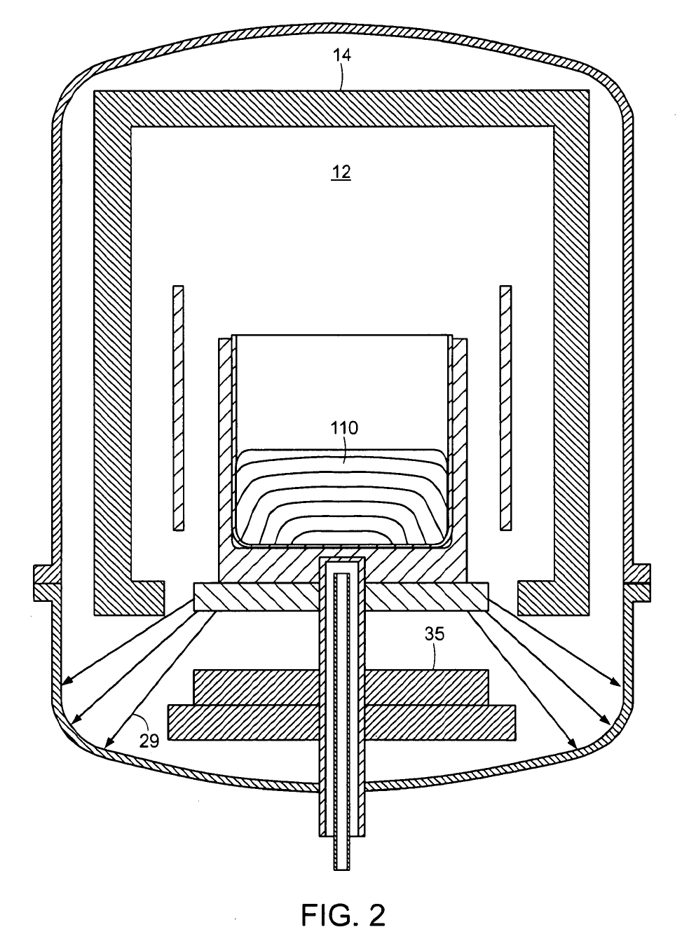

Referring to FIGS. 1 and 2, to produce a monocrystalline ingot according to the subject invention, the furnace 10 should be capable of carrying out directional solidification processes. In a preferred embodiment, the furnace 10 has a cylindrical or square heat zone 12 defined by the area located inside of insulation 14 provided within the furnace 10. The heat zone 12 also includes the crucible 50, and optionally a retainer 70, which is placed on a heat exchanger block 25 and configured to hold the crucible 50 in the heat zone 12. The crucible 50 can be made of quartz or silica, for example, and can be cylindrical or square shaped, and optionally may be coated to prevent cracking of the ingot after solidification. The retainer 70 and the heat exchanger block 25 typically are made of graphite.

The gas-cooled heat exchanger 200 preferably is mounted in the furnace 10 such that it is approximately centered with respect to the at least one heating element 80 in the heat zone 12. The heat exchanger block 25 preferably is attached to the heat exchanger 200, such that at least a portion of the heat exchanger 200 is received within a recess of the heat exchanger block 25.

Insulation 14 is provided along the sides of the furnace 10 and optionally placed above and/or under the crucible 50, such that the insulation 14 is configured to be raised and/or lowered relative to the crucible 50. For example, the insulation 14 can include side insulation 16 and bottom insulation 18, where the side and bottom insulation are configured to be moved together, or alternatively, can be moved separately as desired. The heat exchanger block 25 preferably includes insulation 35 provided directly adjacent to and under the heat exchanger block 25, where the insulation 35 is configured to be moved up and down, as shown in FIGS. 1-3. The insulation 35 is not required in all embodiments.

FIG. 1 shows the heat zone 12 and the crucible 50 with the insulation 14 in a generally closed configuration, and FIG. 2 illustrates the insulation 14 in a generally open configuration. Additionally, as shown in FIG. 2, the insulation 35 provided beneath the heat exchanger block 25 has been moved away from the heat exchanger block 25.

During heat up and melting of the feedstock 90, the configuration shown in FIG. 1 (closed insulation) is used so that heat losses during this stage are minimized During the growth stage, the insulation is gradually opened to increase the radiant heat losses to the water-cooled chamber, eventually resulting in the configuration of the insulation shown in FIG. 2.

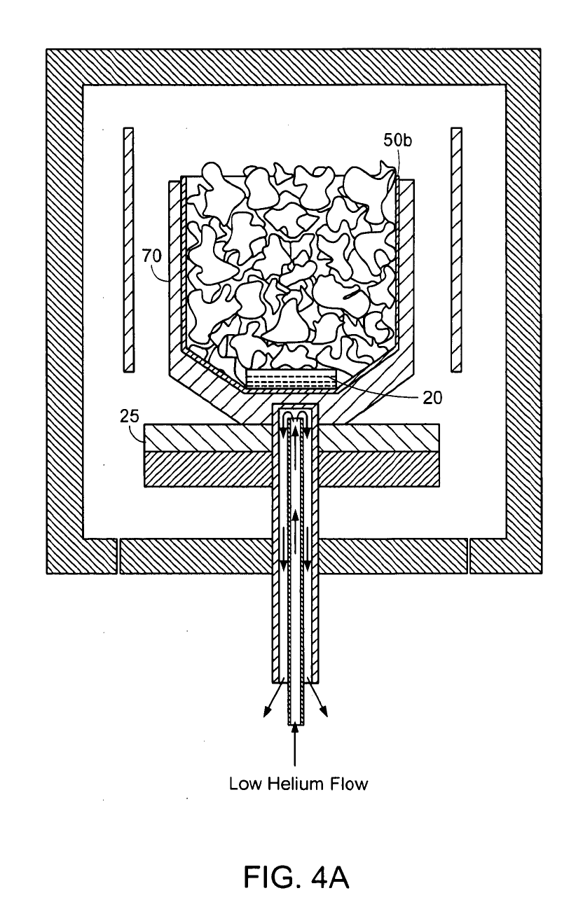

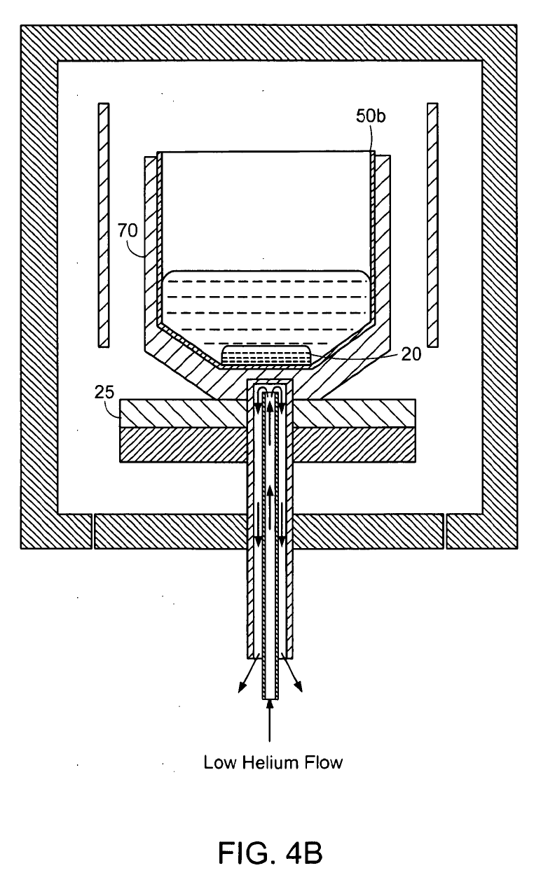

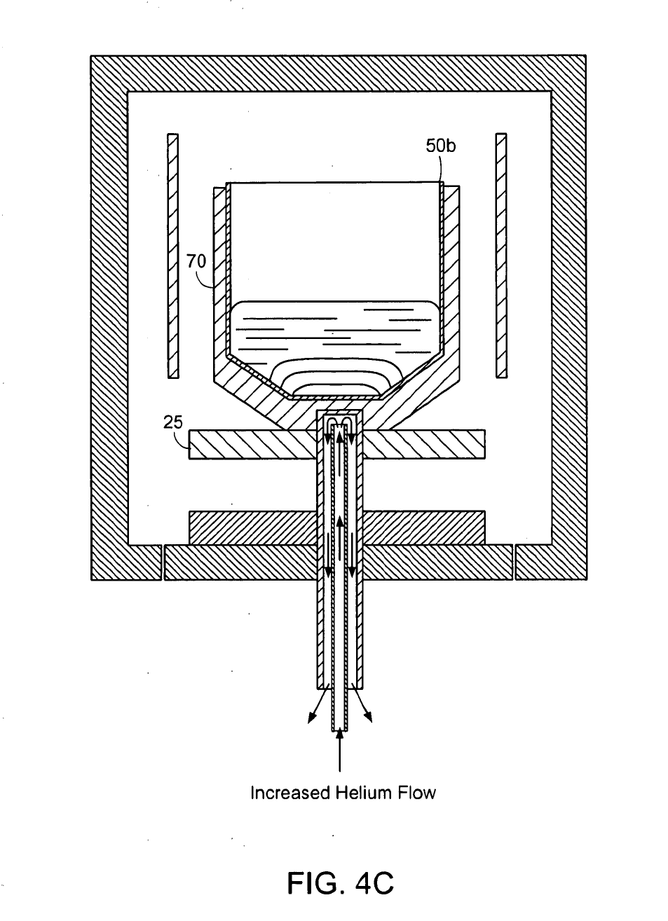

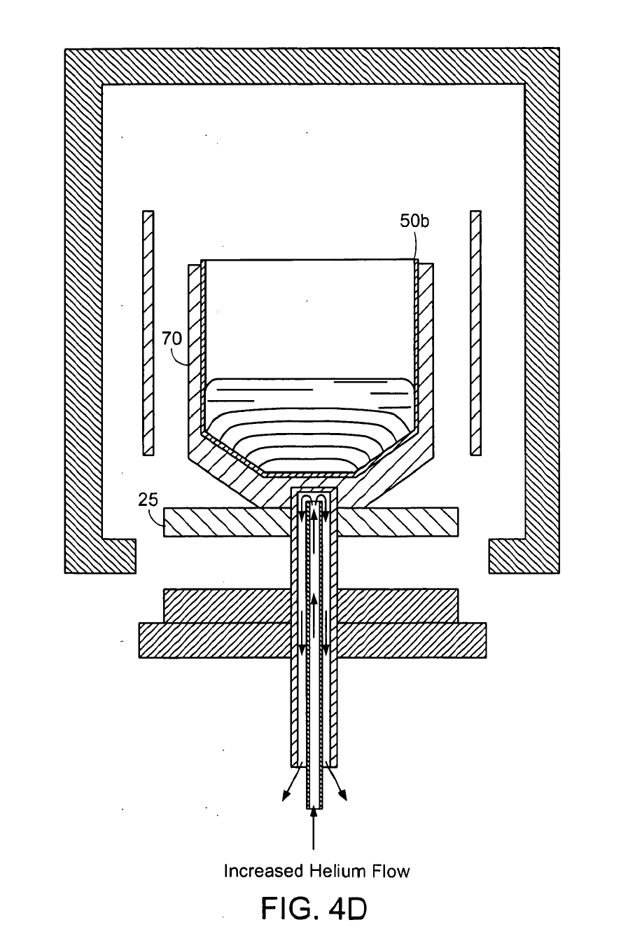

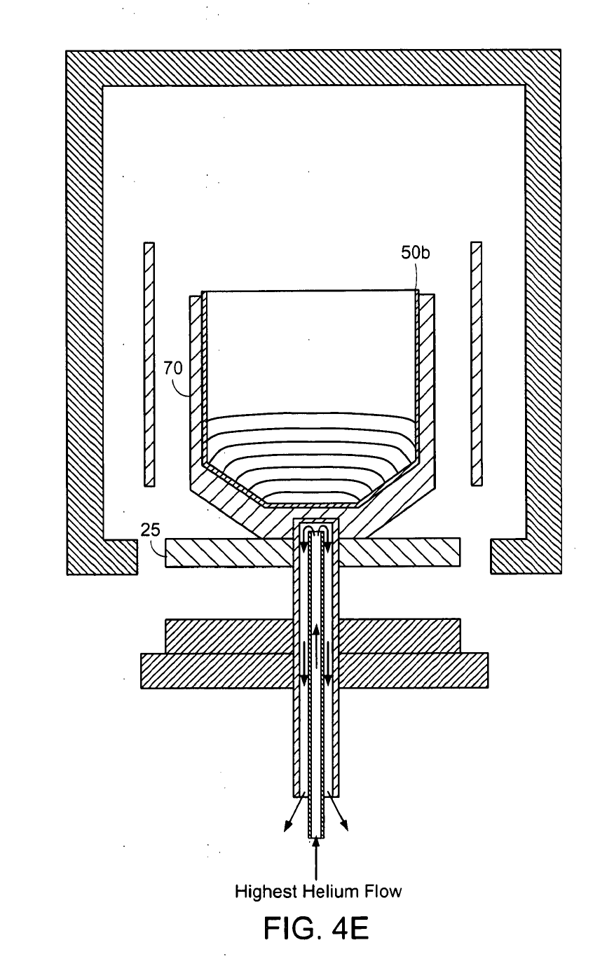

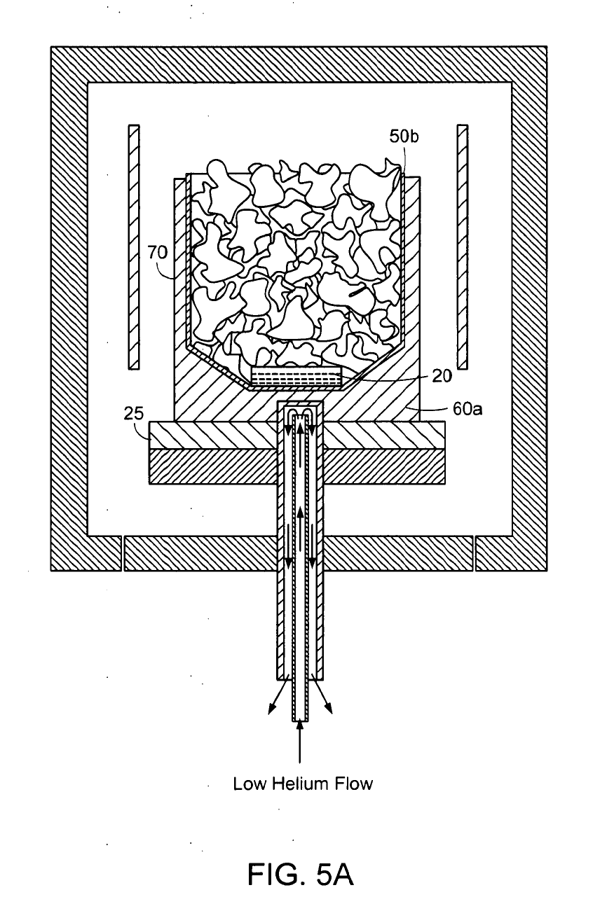

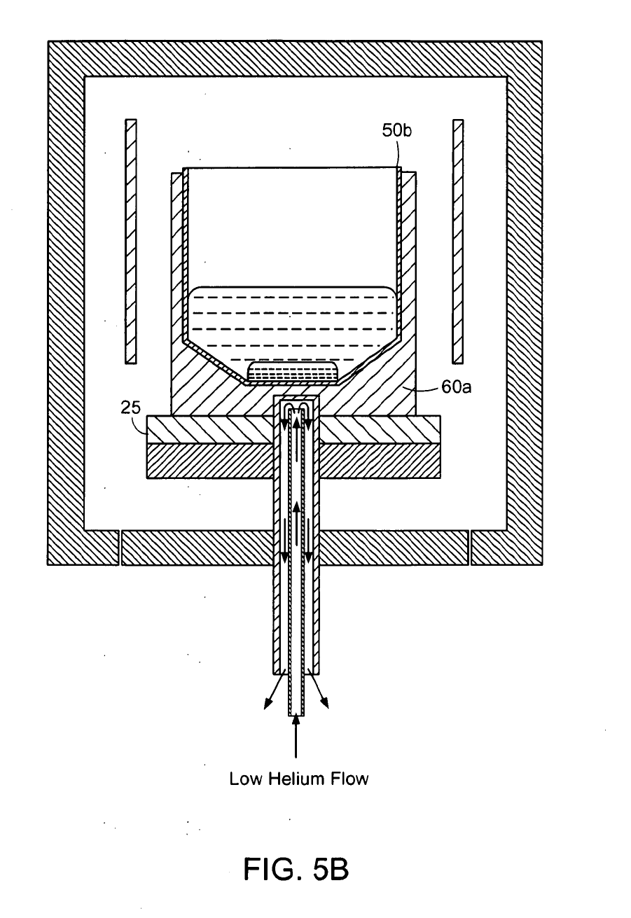

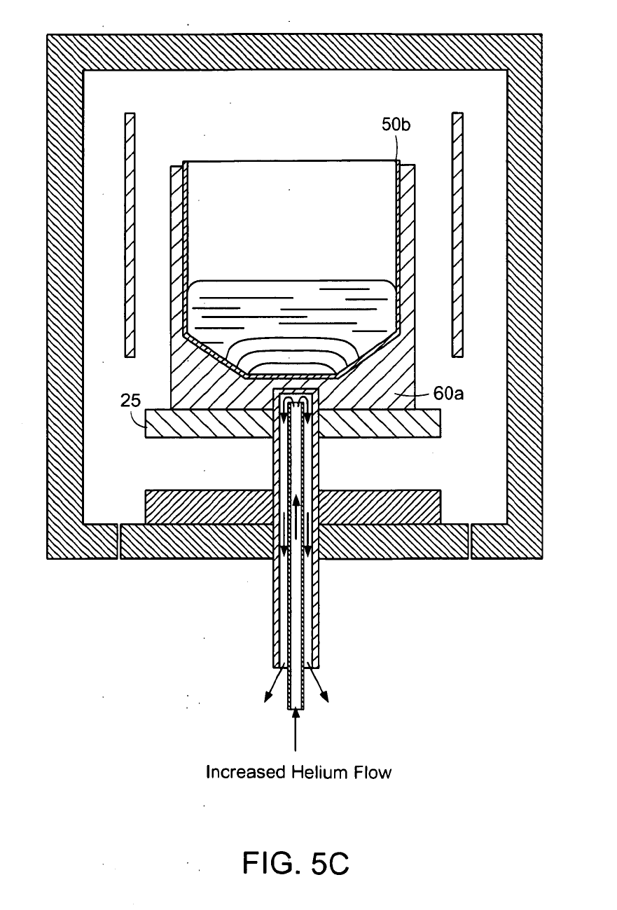

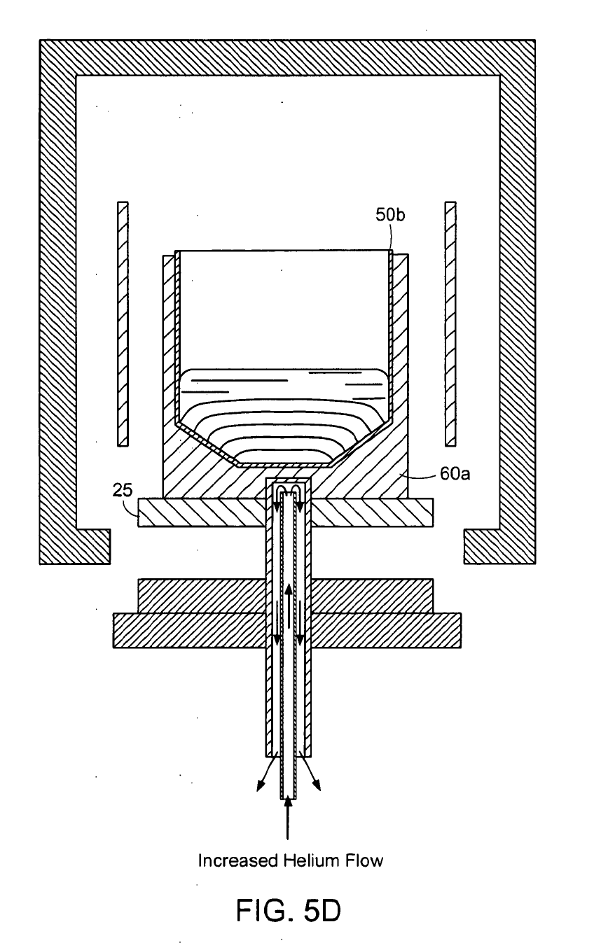

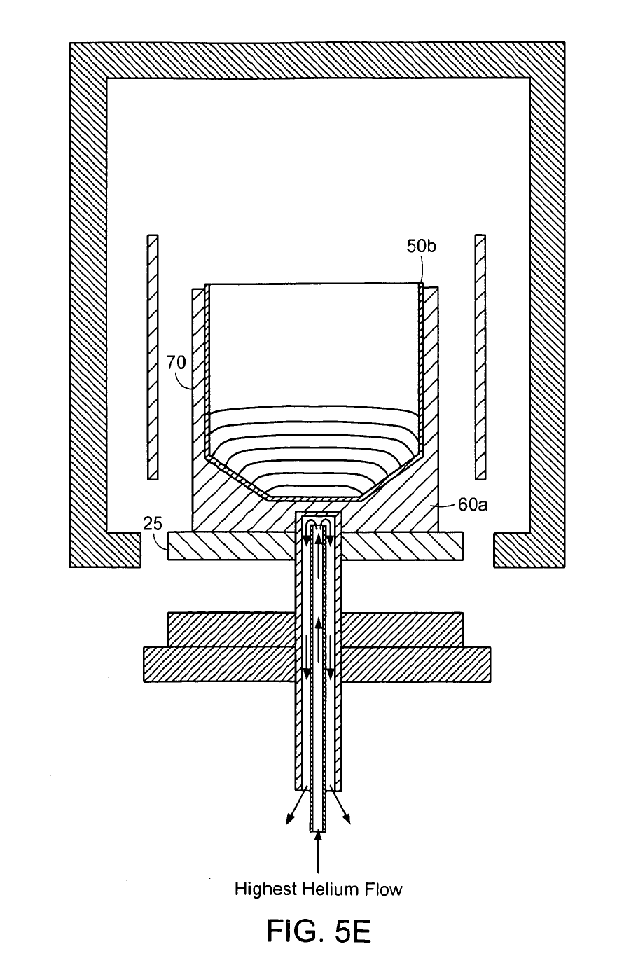

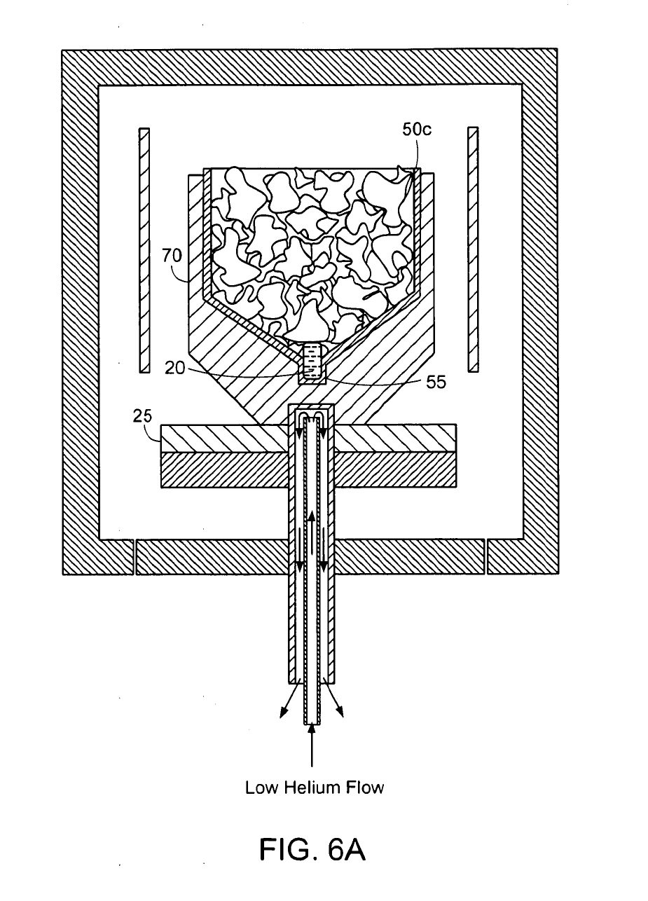

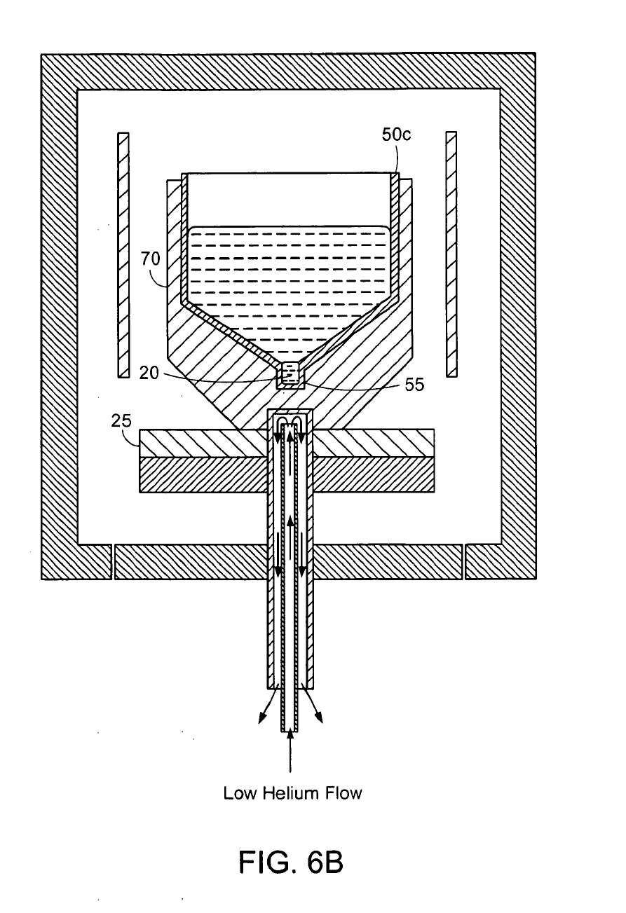

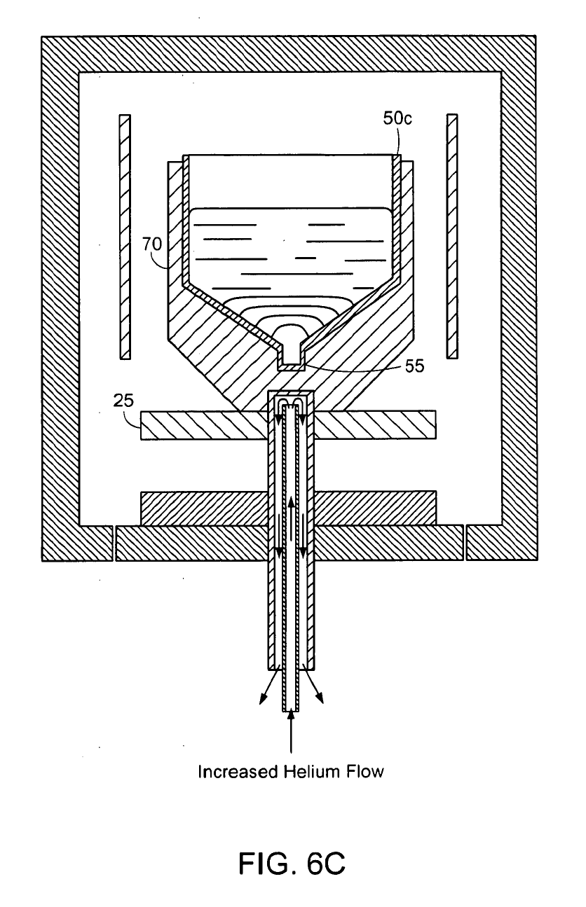

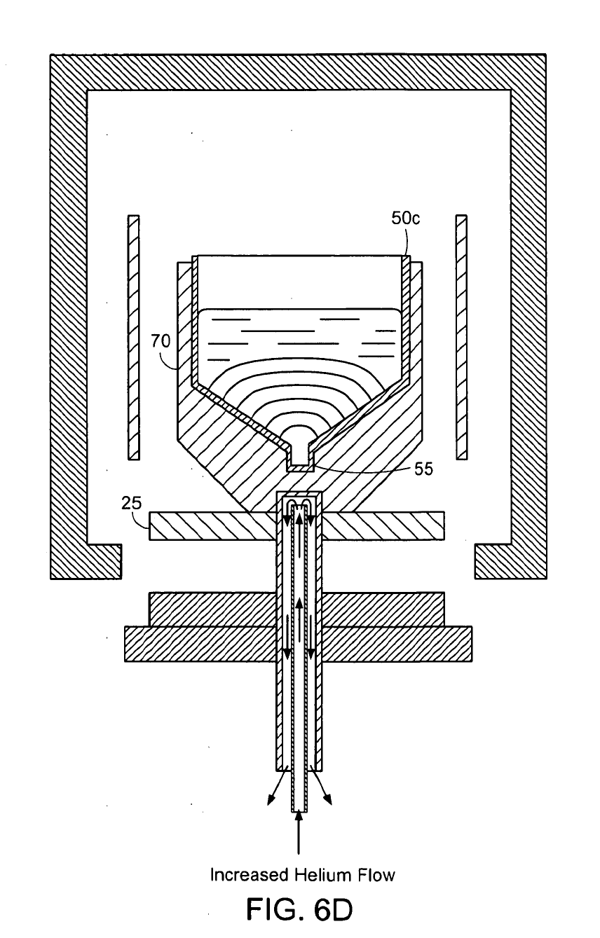

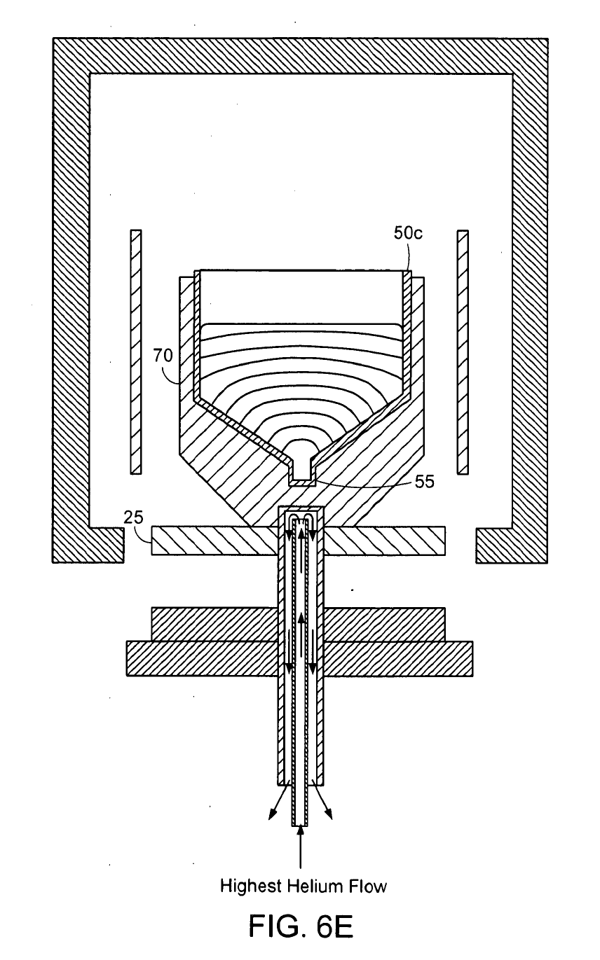

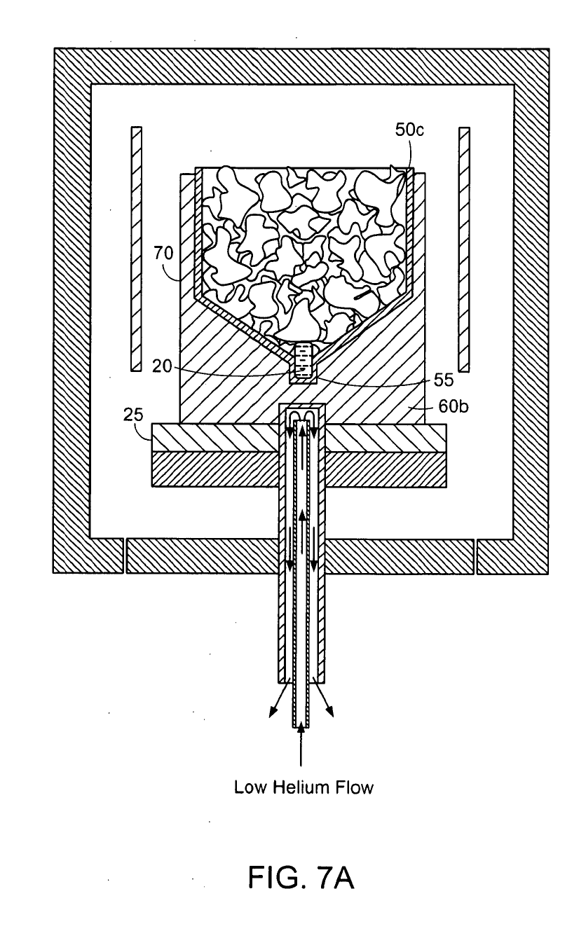

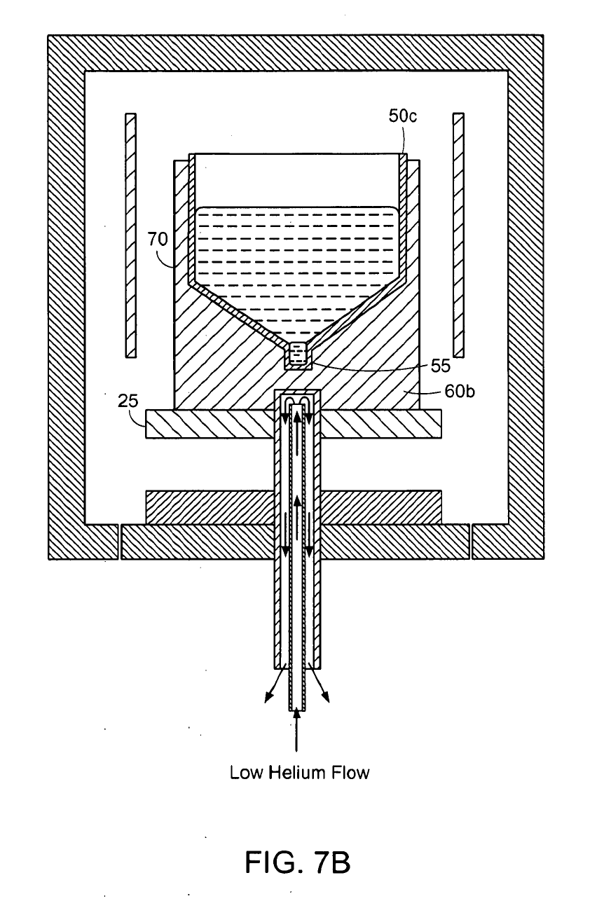

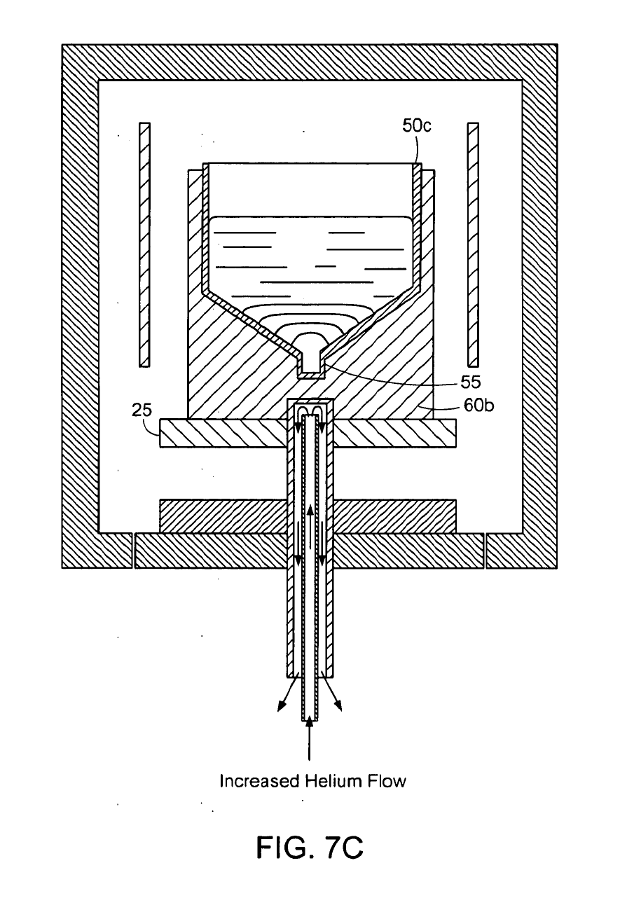

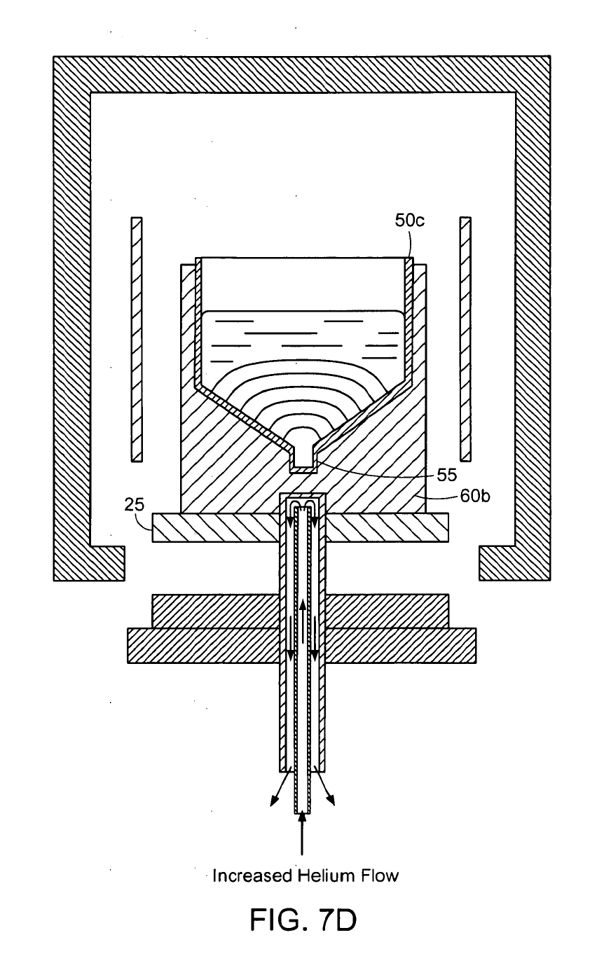

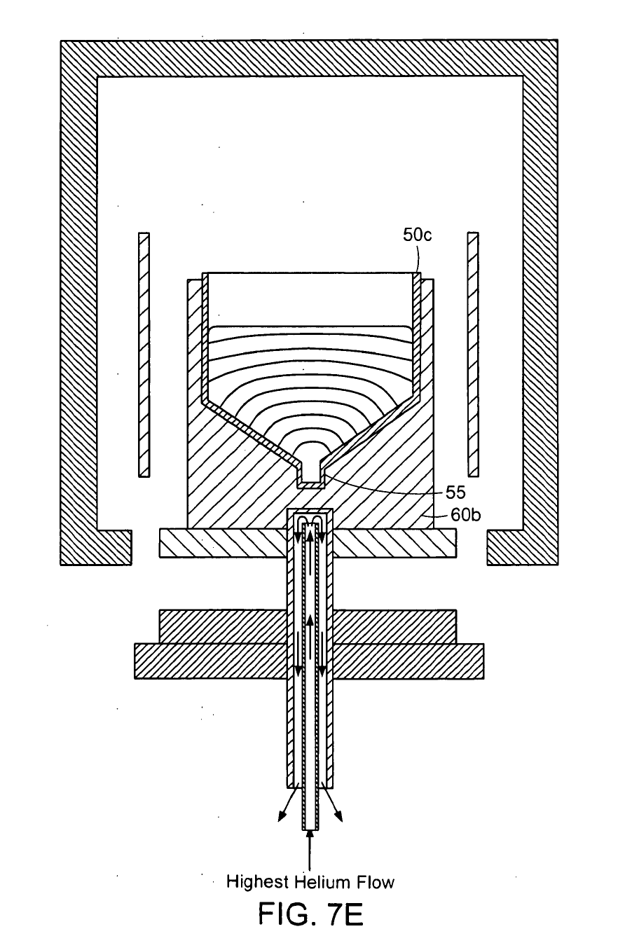

The crucible 50 useful in the furnace 10 of the subject application will now be described in greater detail. According to the subject invention, the crucible 50 may have a number of different geometric configurations. In one embodiment, the crucible 50a has a rectangular shape as shown in FIG. 3A. In other embodiments, a crucible 50b has a conical shape as shown in FIGS. 4A and 5A. In yet other embodiments, a crucible 50c has a tapered shape as shown in FIGS. 6A and 7A. The shape of the crucible 50 is selected based on a desired heat distribution profile, whereby the bottom of the crucible is kept cooler relative to the surface of the top part of the crucible 50 in order to prevent complete melting of the seed crystal. Each of various configurations of the crucible may be used with a flat seed placement as shown in FIG. 1, for example. Alternatively, the crucible may include a seed well 55 at a bottom portion for securing the seed crystal in position during the crystal growth process (see, e.g., FIGS. 6A and 7A).

The crucible 50 preferably is coated with silicon nitride and sintered so that the feedstock 90 and the silicon ingot formed are not in direct contact with the quartz, silica, or other material of the crucible 50. The coating process also can be used to substantially prevent cracking of the silicon ingot after solidification. The coated crucible 50 is then loaded with a monocrystalline silicon seed 20, preferably in approximately the bottom center of the crucible, the seed 20 being covered with silicon feedstock 90. After loading into the furnace 10, the furnace 10 may be evacuated and heat can be applied by the heating element 80.

According to an exemplary embodiment, a monocrystalline silicon ingot can be formed in the furnace 10. The furnace is brought to approximately 1200° C. under vacuum, and the chamber is backfilled with argon gas and the pressure is controlled at a constant value between about 300 mbar and 1000 mbar. Alternatively, other gases such as nitrogen and helium may be used. The pressure within the chamber of the furnace 10 is controlled by regulating the argon gas supplied to the chamber. Heating is then increased and continued until the furnace 10 reaches about 1500° C. and is held at that temperature to achieve melting of silicon feedstock 90. Silicon melts at 1412° C. so the furnace temperature is maintained between about 1415 and 1550° C. When melting starts, the furnace temperature is gradually decreased towards 1415° C. During the melting phase, helium gas flow is initiated through the heat exchanger 200 as shown by the upwards arrows in FIGS. 3B-3E; the pressure and flow of helium gas is controlled separately. Helium preferably is used because of its high thermal conductivity and heat capacity; other gases such as argon, nitrogen, etc. also can be used. During the melting stage, helium flow can be about 50 to 100 SCFH at a pressure between about 5 and 20 psi. This helium flow is to prevent complete melting of the seed crystal 20. After the melt has stabilized and meltback of the seed 20 achieved the helium flow through the heat exchanger can be gradually increased to about 500 SCFH to promote growth of silicon off the melted back seed crystal 20.

It is desirable to minimize spurious nucleation during the growth due to movement of the crucible 50 and the heating element 80. As a result, according to the system and method of the subject invention, the insulation 14 is configured to be moved relative to the crucible 50 and the heating element 80, rather than moving the crucible 50 itself. Radiative heat losses, for example, as shown in FIG. 2 by the arrows 29 pointing away from the heat exchanger block 25, are used to promote directional solidification after the heat exchanger 200 has been used for seeding and growth across the bottom of the crucible 50. In a preferred embodiment, the chamber of the furnace 10 is a water-cooled chamber.

Referring to FIG. 3A, during a loading stage, the monocrystalline seed 20 is loaded into the rectangular-shaped crucible 50a and covered with the silicon feedstock 90. In this stage, as shown in FIG. 1, the insulation 14 is in a generally closed configuration. The heating element 80 heats and melts the feedstock 90, as shown in FIG. 3B, while a flow of gas through the heat exchanger 200 is initiated.

Referring to FIGS. 3B to 3D, as the silicon feedstock 90 begins to melt, helium gas is forced through the heat exchanger 200 to prevent the seed crystal 20 from completely melting. In one embodiment, the melting of the feedstock 90 and the seed crystal 20 can be monitored. For example, a quartz rod probe or thermocouple can be dipped into the melt periodically. As melting of the feedstock 90 and the seed 20 progresses, a temperature inside the furnace 10 is gradually reduced. When a result is achieved such that all of the silicon feedstock 90 has melted with at least some meltback of the seed crystal 20, helium flow through the heat exchanger 200 can be increased gradually to stop the meltback and promote growth of the ingot. According to the subject invention, a temperature of the furnace 10 preferably is maintained just above the melting point of the material to be produced in order to promote controlled directional solidification for essentially all of the feedstock 90. In another embodiment, the heat exchanger 200 and the crucible 50a containing the feedstock 90 can be lowered at a controlled rate in addition to moving of the insulation 14 discussed above. Also, in certain embodiments, the insulation 35 can be placed under the heat exchanger block 25 and lowered to promote radiative heat losses and enhance growth.

As shown in FIG. 3E, substantially complete solidification of the feedstock 90 is achieved by lowering the temperature inside the furnace 10 to just below the melting point of the material to be produced. In the exemplary embodiment described herein, because silicon is being produced, the temperature is reduced to approximately 1412° C. This is done as a means to obtain the desirable solid-liquid interface shape during growth. A convex solid-liquid interface is achieved during growth of the monocrystalline silicon ingot 110 by the heat exchanger 200, and single crystal growth is achieved to cover nearly the entire bottom surface of the ingot 110. After complete solidification, the resulting ingot 110 may be cooled within the heat zone.

FIGS. 4A-4E are cross-sectional schematic views of the directional solidification furnace and monocrystalline growth process having a conical-shaped crucible 50b.

FIGS. 5A-5E also are cross-sectional schematic views of a directional solidification furnace and monocrystalline growth process having a conical-shaped crucible 50b. FIGS. 5A-5E also illustrate a support structure 60a which may be provided at a bottom of the crucible 50b. The support structure 60a is positioned above the heat exchanger block 25, and has a shape which is designed to complement the shape of the crucible 50b so as to mate with the crucible 50b and retainer 70. The support structure 60a functions to provide structural integrity to the system while providing an additional means by which heat flow may be controlled.

FIGS. 6A-6E are cross-sectional schematic views of the directional solidification furnace and monocrystalline growth process having a tapered-shaped crucible 50c with a seed well portion 55 for securing the seed 20 in place.

FIGS. 7A-7E illustrate a directional solidification furnace and monocrystalline growth process having a tapered-shaped crucible 50c with a seed well portion 55 for securing the seed 20 in place, in which a similar corresponding support structure 60b is provided at a bottom of the crucible 50c for added structural integrity, after loading the seed 20 and a charge according to an embodiment of the subject invention. Similar to the support structure 60a, the support structure 60b is positioned above the heat exchanger block 25, and has a shape which is designed to complement the shape of the conical-shaped crucible 50b so as to mate with the conical-shaped crucible 50b and retainer 70.

Although the subject invention has been described with respect to preferred embodiments, those skilled in the art will readily appreciated that changes or alterations in the sequences described or modifications thereto may be made without departing from the spirit or scope of the subject invention as defined by the appended claims.

### INCORPORATION BY REFERENCE

The entire contents of all patents, published patent applications and other references cited herein are hereby expressly incorporated herein in their entireties by reference.

What is claimed is:

1. A system for producing a monocrystalline ingot, comprising:
a crucible provided in a furnace, the crucible configured to receive a single seed crystal and feedstock material;
at least one heating element for heating and at least partially melting the seed crystal, and completely melting the feedstock material contained in the crucible;
a heat exchanger for controlling heat extraction from the crucible, in order to promote growth of the monocrystalline ingot from the at least partially melted seed crystal and the feedstock material; and
insulation contained in the furnace and configured to move relative to the crucible to promote cooling and directional solidification of the monocrystalline ingot.

2. The system of claim 1, wherein the insulation is raised or lowered relative to the crucible.

3. The system of claim 1, wherein the crucible includes a retainer for holding the crucible in the furnace.

4. The system of claim 1, wherein the heat exchanger is operable in a plurality of stages to control a rate of melting of the seed crystal in the crucible.

5. The system of claim 4, wherein in one stage, a gas flows into the heat exchanger to prevent substantially complete melting of the seed crystal.

6. The system of claim 5, wherein in another stage, the gas flow into the heat exchanger is increased to promote directional solidification off the seed crystal.

7. The system of claim 1, further comprising a probe or thermocouple to monitor melting of the feedstock material and meltback of the seed crystal.

8. The system of claim 1, wherein the feedstock material is a polycrystalline silicon feedstock.

9. The system of claim 1, wherein the heat exchanger is a gas-cooled heat exchanger.

10. The system of claim 1, further comprising a heat exchanger block for supporting the crucible.

11. The system of claim 10, wherein the insulation includes at least side insulation and insulation arranged under the heat exchanger block.

12. The system of claim 11, wherein the side insulation is configured to move in a vertical direction relative to the heat exchanger block.

13. The system of claim 11, wherein the insulation arranged under the heat exchanger block is configured to move relative to the heat exchanger block.

14. The system of claim 1, wherein a shape of the crucible is one of a rectangular, conical, or tapered shape.

15. The system of claim 1, wherein the crucible has a seed well portion for securing the seed crystal during monocrystalline growth.

16. The system of claim 1, further comprising a support structure provided with the crucible for controlling heat flow.

17. A method for producing a monocrystalline ingot by directional solidification, comprising the steps of:
placing a seed crystal and feedstock material in a crucible in a furnace;
heating and at least partially melting the seed crystal, and completely melting the feedstock material contained in the crucible;
operating a heat exchanger to control heat extraction from the crucible, in order to promote growth of the monocrystalline ingot from the at least partially melted seed crystal and the feedstock material; and
providing movable insulation in the furnace, the insulation configured to move relative to the crucible to promote directional solidification of the monocrystalline ingot.

18. The method of claim 17, wherein the insulation is raised or lowered relative to the crucible to promote directional solidification off the seed crystal.

19. The method of claim 17, wherein the step of operating the heat exchanger further comprises flowing a gas into the heat exchanger to prevent substantially complete melting of the seed crystal.

20. The method of claim 19, further comprising increasing the gas flow into the heat exchanger to promote directional solidification of the seed crystal.

21. The method of claim 17, wherein the movable insulation includes at least side insulation and insulation arranged under a heat exchanger block.

22. The method of claim 21, further comprising the step of:
raising or lowering the insulation arranged under the heat exchange block to promote directional solidification.

23. A method for producing a monocrystalline silicon ingot useful for photovoltaic applications, comprising the steps of:
placing a seed crystal and silicon feedstock material in a crucible of a furnace;
heating and at least partially melting the seed crystal, and completely melting the feedstock material contained in the crucible;
operating a heat exchanger to control the melting of the seed crystal and the feedstock material by introducing a gas into the crucible at a controlled rate; and
providing movable insulation in the furnace, the insulation configured to move relative to the crucible to promote directional solidification of the monocrystalline ingot.

24. The method of claim 23, wherein the rate of introduction of the gas into the heat exchanger is controlled by feedback obtained by monitoring melting of the feedstock material.

25. The method of claim 23, further comprising the step of increasing a flow of the gas into the heat exchanger to promote directional solidification off the seed crystal.
